(19) United States
(12) Patent Application Publication
(10) Pub. No.: US 2026/0230041 A1
(43) Pub. Date: Aug. 6, 2026

(54) DYNAMICALLY BIASED AMPLIFIER

(71) Applicant: QUALCOMM Incorporated, San Diego, CA (US)

(72) Inventors: Amaresh HEGGADDE SHIVANANDA, Santa Clara, CA (US); Kamal AGGARWAL, Pleasanton, CA (US); Doohwan JUNG, Huntington Beach, CA (US); Hirad SAMAVATI, Santa Clara, CA (US)

(21) Appl. No.: 19/044,316

(22) Filed: Feb. 3, 2025

(51) Int. Cl. H03F 1/30; H03F 1/02; H03F 3/45

(52) U.S. Cl. CPC H03F 1/301; H03F 1/0288; H03F 3/45179; H03F 2200/451; H03F 2200/453; H03F 2200/471

(57) ABSTRACT

Certain aspects of the present disclosure provide techniques for a dynamically biased amplifier. An example radio frequency (RF) circuit includes a first amplifier circuit configured to amplify a signal. The RF circuit further includes a first bias voltage generator comprising a first replica circuit coupled to a second replica circuit, wherein the first bias voltage generator is configured to output a first bias voltage based on a comparison between a first voltage and a second voltage associated with the first replica circuit. The RF circuit further includes a second bias voltage generator coupled to the first bias voltage generator and selectively coupled to the first amplifier circuit, wherein the second bias voltage generator is configured to feed, to the first amplifier circuit, a second bias voltage that is based on the first bias voltage and one or more characteristics of the signal.

### INTRODUCTION

### Field of the Disclosure

Aspects of the present disclosure relate to amplifier circuits, and more particularly, to biasing of amplifier circuits.

### Description of Related Art

Wireless communications systems are widely deployed to provide various telecommunication services such as telephony, video, data, messaging, broadcasts, etc. These wireless communications systems may employ multiple-access technologies capable of supporting communications with multiple users by sharing available wireless communications system resources with those users. Wireless communication devices may communicate radio frequency (RF) signals via any of various suitable radio access technologies (RATs) including, but not limited to, 5G New Radio (NR), Evolved Universal Terrestrial Radio Access (E-UTRA), Code Division Multiple Access (CDMA), Time Division Multiple Access (TDMA), Wideband CDMA (WCDMA), Global System for Mobility (GSM), Bluetooth, Bluetooth Low Energy (BLE), ZigBee, wireless local area network (WLAN) RATs (e.g., Institute of Electrical and Electronics Engineers (IEEE) 802.11 specifications), any future RAT, and/or the like.

In certain cases, a wireless communications device is equipped with a RF transceiver (also referred to as an RF front-end) for communicating RF signals. In general, a baseband signal is modulated to convey information using a modulation technique, such as phase-shift keying (PSK) or any other suitable modulation technique. In a transmit mode, the RF transceiver is responsible for multiplexing the baseband signal with an RF carrier signal that is transmitted over the air (e.g., a wireless communication channel). Such an operation is called upconversion. In a receive mode, the RF transceiver converts a received RF signal to the baseband signal. Such an operation is called downconversion. The received baseband signal then can be demodulated into the information encoded at a transmitter. The RF transceiver may include a cascade of components in a transmit chain and a receive chain, respectively. The cascade of components may include, for example, one or more of attenuators, switches, couplers, filters, mixers, amplifiers, frequency synthesizers, oscillators, antenna tuners, duplexers, diplexers, detectors, etc.

Although there have been great technological advancements in RF circuitry over many years, challenges still exist. For example, RF circuitry (such as an amplifier) can still consume power that exceeds certain specifications associated with operating performance of the RF circuitry. Accordingly, there is a continuous desire to improve the technical performance of RF circuitry, such as amplifier power consumption.

### SUMMARY

Certain aspects provide a radio frequency (RF) circuit. The RF circuit includes a first amplifier circuit configured to amplify a signal. The RF circuit further includes a first bias voltage generator comprising a first replica circuit coupled to a second replica circuit, wherein the first bias voltage generator is configured to output a first bias voltage based on a comparison between a first voltage and a second voltage associated with the first replica circuit. The RF circuit further includes a second bias voltage generator coupled to the first bias voltage generator and selectively coupled to the first amplifier circuit, wherein the second bias voltage generator is configured to feed, to the first amplifier circuit, a second bias voltage that is based on the first bias voltage and one or more characteristics of the signal.

Certain aspects provide a method for operating an RF circuit. The method includes amplifying a first signal via a first amplifier circuit. The method further includes outputting, via a first bias voltage generator that comprises a first replica circuit coupled to a second replica circuit, a first bias voltage based on a comparison between a first voltage and a second voltage associated with the first replica circuit. The method further includes feeding, to the first amplifier circuit via a second bias voltage generator, a second bias voltage that is based on the first bias voltage and one or more characteristics the first signal, wherein the second bias voltage generator is coupled to the first bias voltage generator and selectively coupled to the first amplifier circuit.

Certain aspects provide an RF circuit. The RF circuit includes a transceiver comprising a Doherty amplifier comprising a first amplifier circuit and a second amplifier circuit, wherein the first amplifier circuit is configured to amplify a signal. The transceiver further comprises a first bias voltage generator configured to output a first bias voltage based on a comparison between a first voltage and a second voltage associated with the first amplifier circuit. The transceiver further comprises a second bias voltage generator coupled to the first bias voltage generator and selectively coupled to the first amplifier circuit, wherein the second bias voltage generator is configured to feed, to the first amplifier circuit, a second bias voltage that is based on the first bias voltage and one or more characteristics of the signal.

Other aspects provide: an apparatus operable, configured, or otherwise adapted to perform any one or more of the aforementioned methods and/or those described elsewhere herein; a non-transitory, computer-readable medium comprising instructions that, when executed by a processor of an apparatus, cause the apparatus to perform the aforementioned methods as well as those described elsewhere herein; a computer program product embodied on a computer-readable storage medium comprising code for performing the aforementioned methods as well as those described elsewhere herein; and/or an apparatus comprising means for performing the aforementioned methods as well as those described elsewhere herein. By way of example, an apparatus may comprise a processing system, a device with a processing system, or processing systems cooperating over one or more networks.

To the accomplishment of the foregoing and related ends, the one or more aspects comprise the features hereinafter fully described and particularly pointed out in the claims. The following description and the appended drawings set forth in detail certain illustrative features of the one or more aspects. These features are indicative, however, of but a few of the various ways in which the principles of various aspects may be employed.

### BRIEF DESCRIPTION OF THE DRAWINGS

So that the manner in which the above-recited features of the present disclosure can be understood in detail, a more particular description, briefly summarized above, may be had by reference to aspects, some of which are illustrated in the drawings. It is to be noted, however, that the appended drawings illustrate only certain typical aspects of this disclosure and are therefore not to be considered limiting of its scope, for the description may admit to other equally effective aspects.

FIG. 1 depicts an example wireless communications system.

FIG. 2 depicts an example wireless communications device communicating with another device.

FIG. 3 depicts an example architecture of a dynamically biased amplifier circuit.

FIG. 4 depicts an example architecture of the dynamic bias circuit of FIG. 3.

FIG. 5 depicts an example graph of curves of bias voltage of an example dynamic bias circuit over a range of input powers of an amplifier.

FIG. 6A depicts an example of a multi-stage amplifier architecture employing one or more dynamic bias circuits.

FIG. 6B depicts an example of a Doherty amplifier architecture employing one or more dynamic bias circuits.

FIG. 7 depicts an example selective bias architecture that includes multiple bias circuits.

FIG. 8 depicts an example method for operating a radio frequency circuit that employs a dynamic bias circuit.

To facilitate understanding, identical reference numerals have been used, where possible, to designate identical elements that are common to the figures. It is contemplated that elements disclosed in one aspect may be beneficially utilized in other aspects without specific recitation.

### DETAILED DESCRIPTION

Aspects of the present disclosure provide apparatuses, methods, processing systems, and computer-readable mediums for a dynamically biased amplifier.

A power amplifier (PA) in a radio frequency (RF) transceiver converts a low power signal to a high power signal, for example, for transmission via an antenna. The PA may be configured to feed an RF signal, to an antenna, with adequate power for transmission. As an example, the PA may be formed of relatively wide transistors to carry large currents for the power conversion. In general, the PAs may be the most power-hungry building block of the RF transceiver.

Technical problems for certain PA circuits include, for example, implementing effective power consumption (e.g., efficient power usage) and adequate linearity of an amplifier. In certain cases, a Doherty amplifier may use load modulation to boost the efficiency of the amplifier in a compression region (e.g., a region where the gain of the amplifier decreases as the input amplitude increases). As an example, the Doherty amplifier may include a main amplifier (e.g., a Class A amplifier) and an auxiliary amplifier (e.g., a Class C amplifier). The auxiliary amplifier may provide gain when the main amplifier begins to compress, resulting in an overall gain that can remain relatively constant for higher input and output levels. Thus, the auxiliary amplifier may be operated in two modes. In a power back-off mode, the auxiliary amplifier may be effectively disabled within the linear region of the main amplifier, and in a higher power mode, the auxiliary amplifier may be enabled within the compression region of the main amplifier.

In certain cases, a constant current bias may be applied to the auxiliary amplifier during the power back-off mode and higher power mode. The constant current bias may be set high enough to provide sufficient gain at the higher output levels in which the auxiliary amplifier is enabled. The constant current bias may be a non-trivial amount of current applied to the auxiliary amplifier, for example, during the power back-off mode when the auxiliary amplifier is disabled. Accordingly, the constant current bias may affect the efficiency of the power amplifier circuit, for example, by about 20% of the efficiency.

In certain cases, an adaptive biasing circuit may be used to turn off the auxiliary amplifier during the power back-off mode and turn on the auxiliary amplifier during the higher power mode with a current bias that drives the overall amplifier circuit into a Class AB region (for example, when the main amplifier begins to compress or is in a compression region). As an example, a low constant current bias may be applied during the power back-off mode, and a dynamic current bias may be applied during the higher power mode to enable adequate main-auxiliary amplifier cooperation. The dynamic current bias may be adjusted based on the power level of the input signal, for example, by increasing the current bias as the input power increase.

The overall adaptive biasing circuit may employ an envelope detector circuit along with an adaptive bias circuit that includes active and passive components (e.g., transistors, resistors, and capacitors). Integration of such circuitry into certain RF transceivers (e.g., a wireless wide area network (WWAN) and/or a wireless local area network (WLAN) transceiver) may involve post-fabrication calibration to control process-temperature-voltage (PVT) corners, for example, due to resistor and/or semiconductor device variations.

In certain cases, the envelope detector circuit may feed a bias voltage to multiple adaptive bias circuits for different amplifier stages, for example, including a pre-driver amplifier stage that feeds an output or main amplifier stage. Thus, the single source used to generate a voltage bias for multiple stages may be affected by circuit ground swings or crosstalk.

Certain aspects described herein may overcome the aforementioned technical problem(s), for example, by providing a dynamic biasing circuit that may enable a range of adaptive biasing shifts across different PVT corners associated with amplifier circuitry. The dynamic biasing circuit may include certain replica circuits that provide feedback with respect to the response of PVT corners associated with biasing circuitry and amplifier circuitry. As an example, the dynamic biasing circuit may include a first bias voltage generator and a second bias voltage generator. The first bias voltage generator may feed a first bias voltage to the second bias voltage generator, which may feed an adaptive bias voltage to an amplifier circuit. The first bias voltage generator may include replica circuits that replicate the PVT corners of the second bias voltage generator and the amplifier circuit.

Certain techniques for dynamically biasing an amplifier described herein may provide various beneficial technical effects and/or advantages. The techniques for dynamically biasing an amplifier may enable improved efficiency and/or the like. The improved efficiency (e.g., drain efficiency) may be attributable to the dynamic biasing circuit that may enable biasing across various PVT corners associated with amplifier circuitry. As an example, the compression point of the amplifier circuitry may depend on the PVT corners of semiconductor devices that make up the amplifier and/or biasing circuitry. The dynamic biasing circuit may employ certain replica circuits of the amplifier and biasing circuitry to provide feedback on the corresponding PVT x, as further described herein. Thus, due in part to the PVT corner-based feedback, the dynamic biasing circuit may be capable of applying a specific bias within the linear region and applying a dynamic bias within a compression region, where both regions may depend on the PVT corners associated with the semiconductor devices of the amplifier and biasing circuitry.

### Example Wireless Communications System

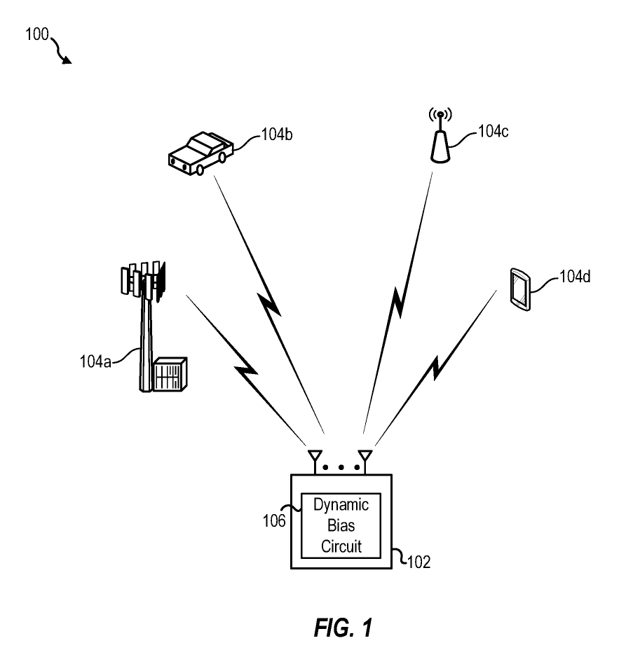

FIG. 1 illustrates an example wireless communications system 100 in which aspects of the present disclosure may be performed. For example, the wireless communications system 100 may include a wireless wide area network (WWAN) and/or a wireless local area network (WLAN). A WWAN may include a New Radio (NR) system (e.g., a Fifth Generation (5G) NR network), an Evolved Universal Terrestrial Radio Access (E-UTRA) system (e.g., a Fourth Generation (4G) network), a Universal Mobile Telecommunications System (UMTS) (e.g., a Second Generation (2G) or Third Generation (3G) network), a code division multiple access (CDMA) system (e.g., a 2G/3G network), any future WWAN system, or any combination thereof. A WLAN may include a wireless network configured for communications according to an Institute of Electrical and Electronics Engineers (IEEE) standard such as one or more of the 802.11 standards, etc. In some cases, the wireless communications system 100 may include a device-to-device (D2D) communications network or a short-range communications system, such as Bluetooth communications or near field communications (NFC).

As illustrated in FIG. 1, the wireless communications system 100 may include a first wireless device 102 communicating with any of various second wireless devices 104a-d (hereinafter “the second wireless device 104”) via any of various radio access technologies (RATs), where a wireless device may refer to a wireless communications device. The RATs may include, for example, WWAN communications (e.g., E-UTRA and/or 5G NR), WLAN communications (e.g., IEEE 802.11), vehicle-to-everything (V2X) communications, non-terrestrial network (NTN) communications, short-range communications (e.g., Bluetooth), D2D communications, etc.

The first wireless device 102 may include any of various wireless communications devices including a user equipment (UE), a base station, a wireless station, an access point, customer-premises equipment (CPE), etc. In certain aspects, the first wireless device 102 includes dynamic bias circuit 106 that may feed a dynamic bias voltage to one or more amplifiers, in accordance with aspects of the present disclosure.

The second wireless device 104 may include, for example, a base station 104a, a vehicle 104b, an access point (AP) 104c, and/or a UE 104d. Further, the wireless communications systems 100 may include terrestrial aspects, such as ground-based network entities (e.g., the base station 104a and/or access point 104c), and/or non-terrestrial aspects, such as a spaceborne platform and/or an aerial platform, which may include network entities on-board (e.g., one or more base stations) capable of communicating with other network elements (e.g., terrestrial base stations) and/or user equipment.

The base station 104a may generally include: a NodeB, enhanced NodeB (eNB), next generation enhanced NodeB (ng-eNB), next generation NodeB (gNB or gNodeB), access point, base transceiver station, radio base station, radio transceiver, transceiver function, transmission reception point, and/or others. The base station 104a may provide communications coverage for a respective geographic coverage area, which may sometimes be referred to as a cell, and which may overlap in some cases (e.g., a small cell may have a coverage area that overlaps the coverage area of a macro cell). A base station may, for example, provide communications coverage for a macro cell (covering relatively large geographic area), a pico cell (covering relatively smaller geographic area, such as a sports stadium), a femto cell (relatively smaller geographic area (e.g., a home)), and/or other types of cells.

The first wireless device 102 and/or the UE 104d may generally include: a cellular phone, smart phone, session initiation protocol (SIP) phone, laptop, personal digital assistant (PDA), satellite radio, global positioning system, multimedia device, video device, digital audio player, camera, game console, tablet, smart device, wearable device, vehicle, electric meter, gas pump, large or small kitchen appliance, healthcare device, implant, sensor/actuator, display, internet of things (IoT) devices, always on (AON) devices, edge processing devices, or other similar devices. A UE may also be referred to more generally as a mobile device, a wireless device, a wireless communications device, a wireless station (STA), a mobile station, a subscriber station, a mobile subscriber station, a mobile unit, a subscriber unit, a wireless unit, a remote unit, a remote device, an access terminal, a mobile terminal, a wireless terminal, a remote terminal, a handset, and other terms.

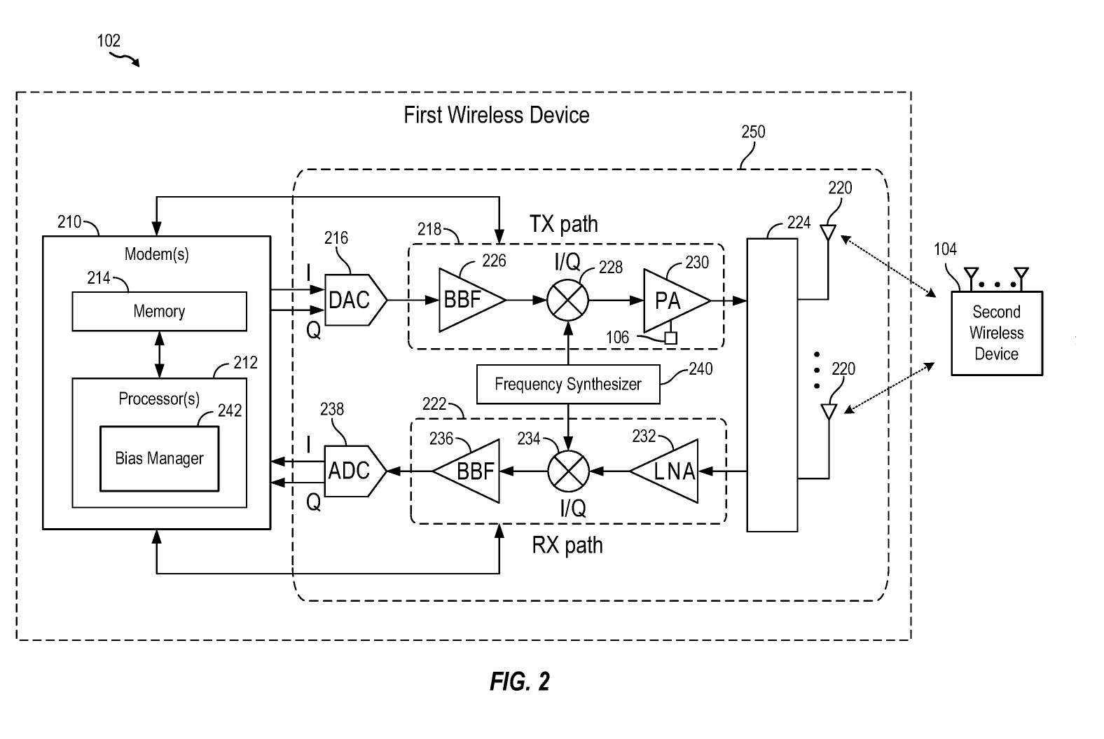

FIG. 2 illustrates example components of the first wireless device 102, which may be used to communicate with any of the second wireless devices 104.

The first wireless device 102 may be, or may include, a chip, system on chip (SoC), system in package (SiP), chipset, package, device that includes one or more modems 210 (hereinafter “the modem 210”). In some cases, the modem 210 may include, for example, any of a WWAN modem (e.g., a modem configured to communicate via E-UTRA, 5G NR, and/or any future WWAN communications standards), a WLAN modem (e.g., a modem configured to communicate via IEEE 802.11 standards), a Bluetooth modem, a NTN modem, etc. In certain aspects, the first wireless device 102 also includes one or more RF transceivers (hereinafter “the RF transceiver 250”). In some cases, the RF transceiver 250 or a portion thereof may be referred to as an RF front end (RFFE). In some aspects, the modem 210 further includes one or more processors, processing blocks or processing elements (hereinafter “the processor 212”) and one or more memory blocks or elements (hereinafter “the memory 214”). In some cases, the processor 212 may implement and/or include a dynamic bias manager 242 that may control certain operations of the dynamic bias circuit 106 as further described herein. In certain aspects, the processor 212 and/or the memory 214 are implemented external or otherwise separate from the modem 210.

In certain aspects, the processor 212 may process any of certain protocol stack layers associated with a radio access technology (RAT). For example, the processor 212 may process any of an application layer, packet layer, WLAN protocol stack layers (e.g., a link or a medium access control (MAC) layer), and/or WWAN protocol stack layers (e.g., a radio resource control (RRC) layer, a packet data convergence protocol (PDCP) layer, a radio link control (RLC) layer, and a MAC layer).

The modem 210 may generally be configured to implement a physical (PHY) layer. For example, the modem 210 may be configured to modulate packets and to output the modulated packets to the RF transceiver 250 for transmission over a wireless medium. The modem 210 is similarly configured to obtain modulated packets received by the RF transceiver 250 and to demodulate the packets to provide demodulated packets. In addition to a modulator and a demodulator, the modem 210 may further include digital signal processing (DSP) circuitry, automatic gain control (AGC), a coder, a decoder, a multiplexer, and/or a demultiplexer (not shown).

As an example, while in a transmission mode, the modem 210 may obtain data from a data source, such as an application processor. The data may be provided to a coder, which encodes the data to provide encoded bits. The encoded bits may be mapped to points in a modulation constellation (e.g., using a selected modulation and coding scheme) to provide modulated symbols. The modulated symbols may be mapped, for example, to spatial stream(s) or space-time streams. The modulated symbols may be multiplexed, transformed via an inverse fast Fourier transform (IFFT) block, and subsequently provided to DSP circuitry for transmit windowing and filtering. The digital signals may be provided to a digital-to-analog converter (DAC) 216. In certain aspects involving beamforming, the modulated symbols in the respective spatial streams may be precoded via a steering matrix prior to provision to the IFFT block.

The modem 210 may be coupled to the RF transceiver 250 by a transmit (TX) path 218 (also known as a transmit chain) for transmitting signals via one or more antennas 220 (hereinafter “the antennas 220”) and a receive (RX) path 222 (also known as a receive chain) for receiving signals via the antennas 220. When the TX path 218 and the RX path 222 share the antennas 220, the paths may be coupled to the antennas 220 via an interface 224, which may include any of various suitable RF devices, such as a balun, a transformer,an antenna tuner, a switch, a duplexer, a diplexer, a multiplexer, and or like. As an example, the modem 210 may output digital in-phase (I) and/or quadrature (Q) baseband signals representative of the respective symbols to the DAC 216. In some examples, all or most of the elements illustrated as being included in the RF transceiver 250 are implemented in a single chip or die. For example, in some configurations, all of the elements of the RF transceiver except the antennas 220 are implemented on a single chip. In some other configurations, the interface 224 or a portion thereof is also omitted from the single chip.

Receiving I or Q baseband analog signals from the DAC 216, the TX path 218 may include a baseband filter (BBF) 226, a mixer 228 (which may include one or several mixers), and a power amplifier (PA) 230. The BBF 226 filters the baseband signals received from the DAC 216, and the mixer 228 mixes the filtered baseband signals with a transmit local oscillator (LO) signal to convert the baseband signal to a different frequency (e.g., upconvert from a baseband frequency to a radio frequency). In some aspects, the frequency conversion process produces the sum and difference frequencies between the LO frequency and the frequencies of the baseband signal. The sum and difference frequencies are referred to as the beat frequencies. Some beat frequencies are in the RF range, such that the signals output by the mixer 228 are typically RF signals, which may be amplified by the PA 230 before transmission by the antennas 220. The antennas 220 may emit RF signals, which may be received at the second wireless device 104. While one mixer 228 is illustrated, several mixers may be used to upconvert the filtered baseband signals to one or more intermediate frequencies and to thereafter upconvert the intermediate frequency signals to a frequency for transmission.

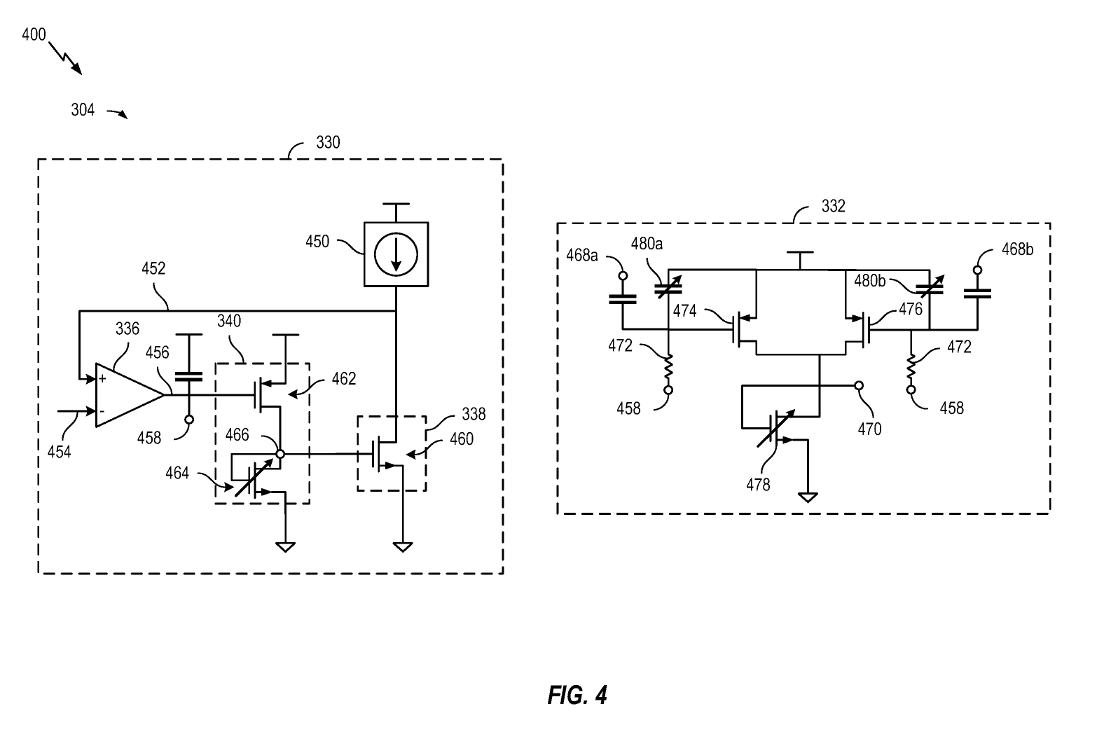

In certain aspects, the PA 230 may be coupled to the dynamic bias circuit 106. The PA 230 may be dynamically biased via the dynamic bias circuit 106, for example, as further described herein with respect to FIGS. 4-8. Dynamically biasing the PA 230 may enable improved efficiency (e.g., drain efficiency) across various PVT corners associated with the semiconductor circuitry of the PA 230.

The RX path 222 may include a low noise amplifier (LNA) 232, a mixer 234 (which may include one or several mixers), and a baseband filter (BBF) 236. RF signals received via the antennas 220 (e.g., from the second wireless device 104) may be amplified by the LNA 232, and the mixer 234 mixes the amplified RF signals with a receive local oscillator (LO) signal to convert the RF signal to a baseband frequency (e.g., downconvert the RF signal to the baseband frequency). The baseband signals output by the mixer 234 may be filtered by the BBF 236 before being converted by an analog-to-digital converter (ADC) 238 to digital I or Q signals for digital signal processing. The modem 210 may receive the digital I or Q signals and further process the digital signals, for example, demodulating the digital signals into information.

Certain transceivers may employ frequency synthesizers with a voltage-controlled oscillator (VCO) to generate a stable, tunable LO frequency with a particular tuning range. Thus, the transmit LO frequency may be produced by a frequency synthesizer 240, which may be buffered or amplified by an amplifier (not shown) before being mixed with the baseband signals in the mixer 228. Similarly, the receive LO frequency may be produced by the frequency synthesizer 240, which may be buffered or amplified by an amplifier (not shown) before being mixed with the RF signals in the mixer 234. Separate frequency synthesizers may be used for the TX path 218 and the RX path 222.

While in a reception mode, the modem 210 may obtain digitally converted signals via the ADC 238 and RX path 222. As an example, in the modem 210, digital signals may be provided to the DSP circuitry, which is configured to acquire a received signal, for example, by detecting the presence of the signal and estimating the initial timing and frequency offsets. The DSP circuitry is further configured to digitally condition the digital signals, for example, using channel (narrowband) filtering, analog impairment conditioning (such as correcting for I/Q imbalance), and applying digital gain to ultimately obtain a narrowband signal. The output of the DSP circuitry may be fed to the AGC, which is configured to use information extracted from the digital signals, for example, in one or more received training fields, to determine an appropriate gain. The output of the DSP circuitry also may be coupled with the demodulator, which is configured to extract modulated symbols from the signal and, for example, compute the logarithm likelihood ratios (LLRs) for each bit position of each subcarrier in each spatial stream. The demodulator may be coupled with the decoder, which may be configured to process the LLRs to provide decoded bits. The decoded bits from all of the spatial streams may be fed to the demultiplexer for demultiplexing. The demultiplexed bits may be descrambled and provided to a medium access control layer (e.g., the processor 212) for processing, evaluation, or interpretation.

The modem 210 and/or processor 212 may control the transmission of signals via the TX path 218 and/or reception of signals via the RX path 222. In some aspects, the modem 210 and/or processor 212 may be configured to perform various operations, such as those associated with any of the methods described herein. The modem 210 and/or processor 212 may include a microcontroller, a microprocessor, an application processor, a baseband processor, a MAC processor, an artificial intelligence (AI) processor, a digital signal processor (DSP), an application specific integrated circuit (ASIC), a field programmable gate array (FPGA) or other programmable logic device (PLD), discrete gate or transistor logic, discrete hardware components, or any combination thereof. The memory 214 may store data and program codes (e.g., processor-readable instructions) for performing wireless communications as described herein. In some cases, the memory 214 may be external to the modem 210 and/or processor 212 and/or incorporated therein (as illustrated with the memory 214 or being incorporated with the processor 212).

FIG. 2 shows an example transceiver design. It will be appreciated that other transceiver designs or architectures may be applied in connection with aspects of the present disclosure. For example, while examples discussed herein utilize I and Q signals (e.g., quadrature modulation), those of skill in the art will understand that components of the transceiver may be configured to utilize any other suitable modulation, such as polar modulation. As another example, circuit blocks may be arranged differently from the configuration shown in FIG. 2, and/or other circuit blocks not shown in FIG. 2 may be implemented in addition to or instead of the blocks depicted.

### Example Dynamically Biased Amplifier

Aspects of the present disclosure provide apparatuses and methods for a dynamic biasing circuit that may enable a range of adaptive biasing shifts across different PVT corners associated with amplifier circuitry. Dynamically biasing an amplifier as described herein may enable improved efficiency (such as drain efficiency) and/or the like.

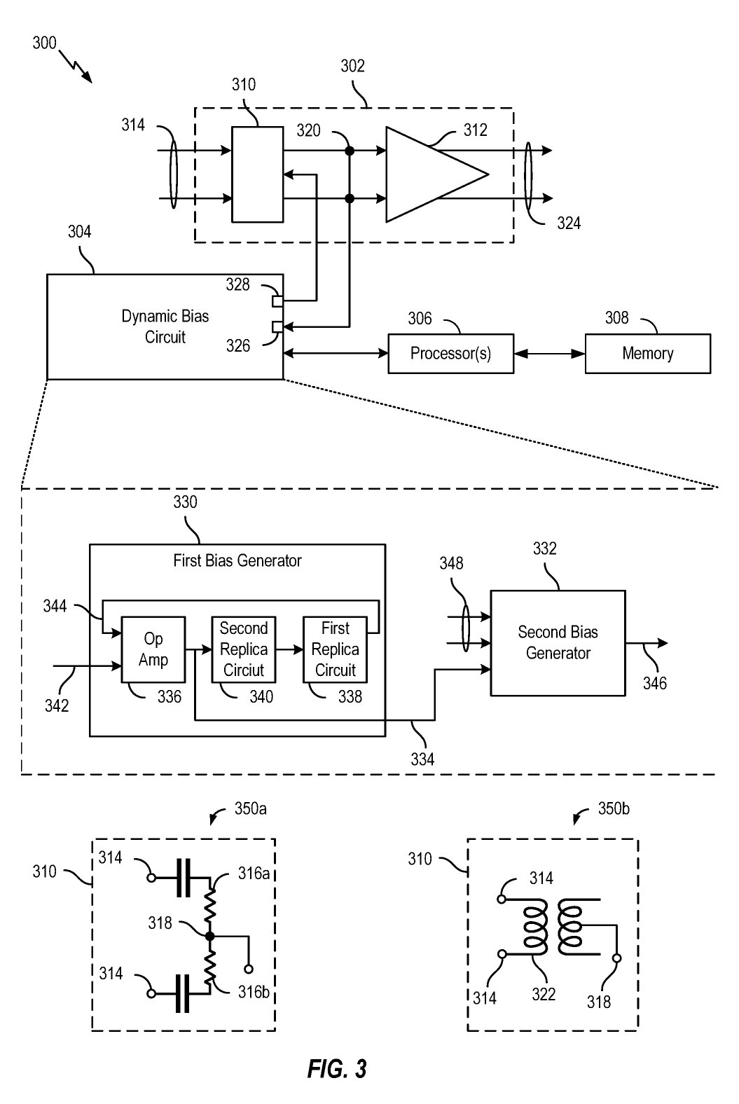

FIG. 3 depicts an example architecture 300 of a dynamically biased amplifier circuit. The architecture 300 may be an example of an RF circuit that includes an amplifier circuit 302 and a dynamic bias circuit 304. The architecture 300 may be an example of (processor-controlled) amplifier circuitry that may be part of a transceiver, such as the RF transceiver 250 of FIG. 2. As an example, the amplifier circuit 302 may be an example of the PA 230 of FIG. 2, and the dynamic bias circuit 304 may be an example of the dynamic bias circuit 106 of FIGS. 1 and 2.

In certain cases, the architecture 300 may further include one or more processors (hereinafter “the processor 306”) and one or more memories (hereinafter “the memory 308”) coupled with the processor 306. The processor 306 may be coupled to the dynamic bias circuit 304. The processor 306 may be an example of the modem 210 and/or the processor 212 of FIG. 2, and the memory 308 may be an example of the memory 214 of FIG. 2. The memory 308 may store data and program codes (e.g., processor-readable instructions) for controlling the dynamic bias circuit 304 via the processor 306 as further described herein. In certain aspects, the processor 306 may implement and/or include the dynamic bias manager 242 of FIG. 2.

The amplifier circuit 302 may be configured to amplify a signal (such as a differential RF signal). In certain cases, the amplifier circuit 302 may be or include a power amplifier circuit, which may be used in a transmit chain, for example, as described herein with respect to FIG. 2. The amplifier circuit 302 may include a differential input stage 310 and an amplifier 312, including, for example, a power amplifier, a driver amplifier, and/or the like. The differential input stage 310 may be circuitry that includes differential input ports 314 and a common mode node 318, as further described herein. The differential input stage 310 may be coupled to differential input ports 320 of the amplifier 312. The dynamic bias circuit 304 may feed a bias voltage to the common mode node 318 to control the common mode voltage of a differential input signal.

As depicted in a first example 350a, the differential input stage 310 may include a first resistive element 316a and a second resistive element 316b coupled in series with each other across the differential input ports 314. Each of the first resistive element 316a and the second resistive element 316b may be or include one or more resistors. The first resistive element 316a and the second resistive element 316b may have the same resistance or a resistance within a threshold difference of each other (e.g., e.g., ± 1%, 5%, or the like). The common mode node 318 may be arranged between the first resistive element 316 and the second resistive element 316b to apply a bias voltage to a common mode voltage of a differential signal.

As shown in a second example 350b, the differential input stage 310 may be or include an inductive element 322, such as an inductor, a transformer, and/or a balun. In this example, the inductive element 322 may include a transformer comprising a primary winding and a secondary winding. The input ports of the primary winding may be the differential input ports 314, and a center tap of the secondary winding may be the common mode node 318 of the differential input stage 310.

The amplifier 312 may be or include a power amplifier, a low noise amplifier, a driver amplifier (e.g., a pre-driver amplifier), or the like. In certain cases, the amplifier 312 may be or include a fully differential amplifier having differential input ports 320 and differential output ports 324. The amplifier 312 may include a transistor amplifier topology, such as a common-source amplifier, a common-gate amplifier, and/or the like. In certain cases, the amplifier 312 may include a complementary metal-oxide-semiconductor (CMOS) transistor topology. In certain cases, the amplifier 312 may include a cascode topology, for example, a common-gate cascode stage and/or the like. As an example, the amplifier 312 may include an input stage (such as a common-source amplifier or a common-gate amplifier) that drives one or more cascode stages (such as a common-gate cascode stage). In certain cases, the input stage may be referred to as a transconductance (gₘ) device of the amplifier 312, and the cascode stage may be referred to as the cascode device of the amplifier 312.

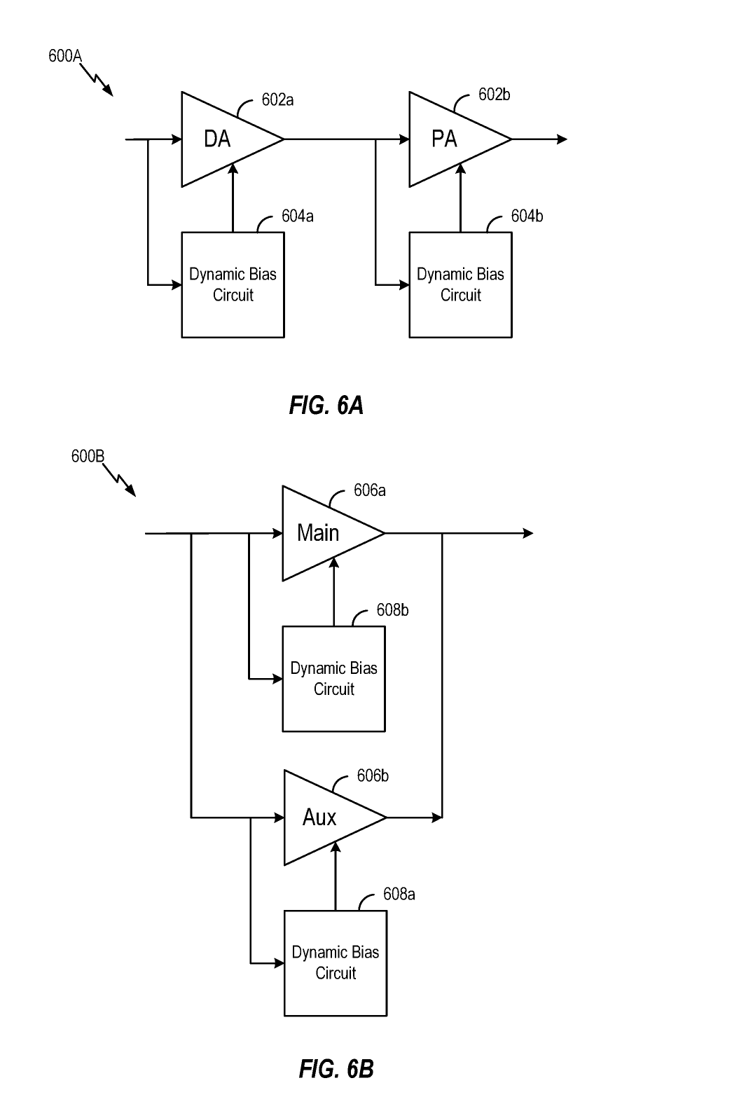

In certain cases, the amplifier 312 may include a Doherty amplifier (such as a CMOS Doherty amplifier) or a portion thereof, such as a main amplifier (e.g., a Class A amplifier, a Class B amplifier, and/or a Class AB amplifier) and/or an auxiliary amplifier (e.g., a Class C amplifier) of a Doherty amplifier circuit, for example, as further described herein with respect to FIG. 6B. As an example, the amplifier 312 may be an example of the main amplifier in a Doherty amplifier. As another example, the amplifier 312 may be an example of the auxiliary amplifier in a Doherty amplifier.

The dynamic bias circuit 304 is coupled to the amplifier circuit 302. The dynamic bias circuit 304 feeds a bias voltage to the common mode node 318 of the differential input stage 310 based at least in part on the RF signal fed to the amplifier 312. The dynamic bias circuit 304 includes input ports 326 coupled to the differential input ports 320 of the amplifier 312. The dynamic bias circuit 304 includes an output port 328 coupled to the common mode node 318 of the differential input stage 310. The dynamic bias circuit 304 may output the bias voltage using a feedback loop to sense the PVT corners associated with certain semiconductor circuitry, such as the gₘ device of the amplifier 312 and/or at least a portion of the dynamic bias circuit 304. The PVT corners may include processor corners including a baseline (e.g., typical) corner, a fast corner, and a slow corner. The fast corner and the slow corner may correspond to carrier mobilities that are higher or lower than the baseline or typical process corner, respectively. The PVT corners may include operational states across a range of supply voltages and/or a range of operating temperatures. The dynamic bias circuit 304 may output the bias voltage with a specific voltage value (e.g., a constant value or within a threshold voltage range) when the input power applied to the amplifier 312 is below a certain input power threshold. When the input power applied to the amplifier 312 is above the input power threshold, the dynamic bias circuit 304 may output the bias voltage with an adaptive voltage value, for example, depending on the PVT corners of the amplifier circuit 302 and/or the dynamic bias circuit 304.

The dynamic bias circuit 304 may include a first bias voltage generator (hereinafter “the first bias generator 330”) and a second bias voltage generator (hereinafter “the second bias generator 332”). The second bias generator 332 may be coupled to the first bias generator 330 and the amplifier circuit 302. The first bias generator 330 may be configured to output a first bias voltage 334, which may be fed to the second bias generator 332. The first bias generator 330 may include an operational amplifier 336, a first replica circuit 338, and a second replica circuit 340. The first bias generator 330 may output the first bias voltage 334 based at least in part on a comparison between a first voltage 342 (e.g., a reference voltage) and a second voltage 344 associated with the first replica circuit 338 and/ or the amplifier 312. The first voltage 342 may be a reference voltage set to a voltage value associated with the input power threshold that distinguishes a constant bias region (e.g., a power back-off mode) and an adaptive bias region (e.g., an on mode) among the bias regions applied to the amplifier 312. The second voltage 344 may be indicative of a voltage response of the amplifier 312 (such as the g m device of the amplifier 312) as replicated at least in part by the first replica circuit 338.

As an example, the operational amplifier 336 may be used to compare the first voltage 342 and the second voltage 344 output by the first replica circuit 338. The first voltage 342 may be fed to an inverting input port of the operational amplifier 336, and the second voltage 344 may be fed to a non-inverting input port of the operational amplifier 336. The second replica circuit 340 may be coupled between the operational amplifier 336 and the first replica circuit 338. The second replica circuit 340 may be configured to replicate the response of the second bias generator 332, and the first replica circuit 338 may be configured to replicate the response of the g m device (or the input stage) of the amplifier 312, as further described herein with respect to FIG. 4.

The second bias generator 332 may be configured to feed, to the common mode node 318, a second bias voltage 346 based on the first bias voltage 334 and one or more characteristics of the RF signal 348 fed to the amplifier 312. The one or more characteristics of the RF signal 348 may be or include a power level, a current level, and/or a voltage level associated with the RF signal 348, for example, in terms of differential signal(s) and/or a common-mode signal of the RF signal 348. For example, the second bias generator 332 may obtain the RF signal 348 via the input ports 326 of the dynamic bias circuit 304, and the second bias generator 332 may output the second bias voltage 346 via the output port 328 of the dynamic bias circuit 304.

The second bias generator 332 may be or include a voltage peak detector, for example, as further described herein with respect to FIG. 4. In certain cases, the voltage peak detector may compare a characteristic of the RF signal 348 (e.g., a voltage level) to a supply or reference voltage. The common-mode voltage of the RF signal 348 may be biased at least in part by an output of the operational amplifier 336. The second bias generator 332 may include certain variable passive and/or active electrical components, such as one or more variable capacitors and/or one or more transistors, to control the slope of the adaptive bias region of the dynamic bias circuit 304, for example, as further described herein.

The processor 306 controls certain operation(s) of the dynamic bias circuit 304. In certain cases, the processor 306 may control the value of the reference voltage (e.g., the first voltage 342) fed to the operational amplifier 336. In certain cases, the processor 306 may control the capacitance and/or resistance of certain component(s) of the second bias generator 332 to adjust the slope of the adaptive bias region, for example, depending on the PVT corner encountered.

FIG. 4 depicts an example architecture 400 of the dynamic bias circuit 304 of FIG. 3. In this example, the dynamic bias circuit 304 includes the first bias generator 330 coupled to the second bias generator 332.

As discussed with respect to FIG. 3, the first bias generator 330 may include the operational amplifier 336, the first replica circuit 338, and the second replica circuit 340. The first bias generator 330 may further include a current source 450. The operational amplifier 336 includes a first input 452 (e.g., a non-inverting input port), a second input 454 (e.g., an inverting input port), and an output 456. A reference voltage may be fed to the second input 454 of the operational amplifier 336. As discussed, the reference voltage may be set to a voltage value based on a threshold voltage that distinguishes a constant bias region (e.g., a power back-off mode) and an adaptive bias region (e.g., an on mode) among the bias regions applied to an amplifier (such as the amplifier 312). The current source 450 may be coupled to the first input 452 of the operational amplifier 336. The current source 450 may be or include a transistor current source. The current source 450 may be set to provide an electric current level that tracks the expected output current of the amplifier 312. The first replica circuit 338 may be coupled to the first input 452 of the operational amplifier 336, and the second replica circuit 340 may be coupled between the output 456 of the operational amplifier and the first replica circuit 338. The output 456 of the operational amplifier 336 may be coupled to the second bias generator, for example, a common mode node 458 of the second bias generator.

The first bias generator 330 includes a multi-stage feedback loop based on the second replica circuit 340, the first replica circuit 338, and/or the current source 450. A first voltage output by the operational amplifier 336 may be fed to the input of the second replica circuit 340, which may replicate at least portion of the second bias generator 332, as further described herein. The second replica circuit 340 feeds a second voltage to the first replica circuit 338, which may replicate at least a portion of the amplifier (e.g., the g m device of the amplifier 312), as further described herein. The second voltage may replicate or emulate the bias voltage output by the second bias generator 332. The first replica circuit 338 feeds a third voltage to the first input 452 of the operational amplifier 336. The third voltage may replicate or emulate the output voltage of the amplifier 312. Accordingly, the multi-stage feedback loop of the first bias generator 330 may enable amplifier biasing across various PVT corners associated with amplifier circuitry, for example, due to responses of the replica circuits 338, 340.

In the feedback loop of the first bias generator 330, the replica circuits 338, 340 may provide feedback associated with the PVT corners of certain semiconductor device(s) that make up the g m device of the amplifier 312 and/or the second bias generator 332. The first replica circuit 338 may provide feedback associated with the g m device of the amplifier 312. The first replica circuit 338 may include at least one replica transistor associated with the amplifier circuit 302, such as the g m device of the amplifier 312. The first replica circuit 338 may include a semiconductor device that replicates at least a portion of the transistor topology of the amplifier 312 of FIG. 3. The first replica circuit 338 may replicate the input stage of the amplifier 312, such as a common-source input stage and/or a common-gate input stage. The first replica circuit 338 may include a transistor 460. As an example of a common-source input stage (e.g., g m device), a gate of the transistor 460 may be coupled to an output node of the second replica circuit 340, and a drain of the transistor 460 may be coupled to the first input 452 of the operational amplifier 336. Accordingly, the transistor 460 may be a replica (in terms of physical dimensions and process fabrication) of a g m device of the amplifier 312.

The second replica circuit 340 may provide feedback associated with the second bias generator 332. The second replica circuit 340 may include at least one replica transistor associated with the second bias generator 332. In certain cases, the second replica circuit 340 may be or include a single-ended replica of the differential architecture of the second bias generator 332. As an example, the second replica circuit 340 may include a first transistor 462, a second transistor 464, and an output node 466. A gate of the first transistor 462 may be coupled to the output 456 of the operational amplifier 336, and the output node 466 may be coupled between a drain of the first transistor 462 and a gate of the second transistor 464. Accordingly, the first transistor 462 and the second transistor 464 of the second replica circuit 340 may be replicas of the first transistor 474 (or the second transistor 476 ) and the third transistor 478 of the second bias generator 332, respectively, as further described herein. The replica transistor(s) 460, 462, 464 of the first replica circuit 338 and/or the second replica circuit 340 may include a channel having at least one dimension (e.g., a width, length, and/or depth) that matches a respective dimension of a transistor of the amplifier circuit 302 and/or the second bias generator 332 within a threshold (e.g., ± 1%, 5%, or the like).

The second bias generator 332 may be configured to feed a bias voltage to the common mode node 318 of the amplifier circuit 302 of FIG. 3, as described herein. The second bias generator 332 may be or include a voltage peak detector, for example, biased at least in part by the output of the operational amplifier 336 of the first bias generator 330. In certain aspects, the second bias generator 332 may include a variable voltage divider (e.g., the third transistor 478) coupled to the voltage peak detector. In certain aspects, the second bias generator 332 may include variable capacitors 480a, 480b coupled to the voltage peak detector. The variable voltage divider and/or the variable capacitors may be used to adjust the slope of the adaptive bias region applied to the amplifier circuit 302.

The second bias generator 332 may include a first differential input port 468a, a second differential input port 468b, and an output node 470. The common mode node 458 of the second bias generator 332 may be coupled between the first differential input port 468a and the second differential input port 468b. The common mode node 458 may be arranged between resistors 472 coupled in series with each other, for example, as described herein with respect to the first example differential input stage of FIG. 3. The first differential input port 468a of the second bias generator 332 may be coupled to a first differential input port of the amplifier circuit 302 of FIG. 3, and the second differential input port of the second bias generator may be coupled to a second differential input port of the amplifier circuit 302 of FIG. 3. The output node 470 of the second bias generator 332 may be coupled to the common mode node 318 of the amplifier circuit 302.

The second bias generator 332 may include a first transistor 474, a second transistor 476, and a third transistor 478. The first transistor 474 may have a gate coupled to the first differential input port 468a and a drain coupled to the output node 470. The second transistor 476 may have a gate coupled to the second differential input port 468b and a drain coupled to the output node 470. Each of the first transistor 474 and the second transistor 476 may be or include one or more P-channel (e.g., P-MOS) transistors. Thus, the first transistor 474 and the second transistor 476 may operate as a differential voltage peak detector with inputs biased by the output of the operational amplifier 336 of the first bias generator 330. The third transistor 478 may have a drain and a gate coupled to the output node 470. The third transistor 478 may be or include one or more N-channel (e.g., N-MOS) transistors. The third transistor 478 may operate as a variable voltage divider to control the voltage level at the output node 470. The third transistor 478 may include an adjustable or variable resistance, for example, a switched network of transistors to select one or more transistors that provide the expected voltage level at the output node 470.

In certain cases, the second bias generator 332 may include a first variable capacitor 480a and a second variable capacitor 480b. The first variable capacitor 480a may be coupled to the first differential input port 468a. For example, the first variable capacitor 480a may be coupled between a supply voltage and the first differential input port 468a. The second variable capacitor 480b may be coupled to the second differential input port 468b. As an example, the second variable capacitor 480b may be coupled between the supply voltage and the second differential input port 468b. Each of the first variable capacitor 480a and the second variable capacitor 480b may be or include one or more of a tantalum capacitor, aluminum capacitor, ceramic capacitor, varactor, a metal-insulator-metal (MIM) capacitor, metal-oxide-metal (MOM) capacitor, a metal-oxide-semiconductor (MOS) capacitor, a metal fringe capacitor, a trench capacitor, a junction capacitance of a diode or transistor, or the like.

In certain aspects, one or more processors (e.g., the processor 306 of FIG. 3) may be coupled to the second bias generator 332. The processor(s) may be configured to adjust the bias voltage at the output node 470 of the second bias generator 332 based at least in part on a first capacitance of the first variable capacitor 480a, a second capacitance of the second variable capacitor 480b, and a drain-source resistance of the third transistor 478. The third transistor 478 may be used to adjust the voltage level at the output node 470 based on the adjustable drain-source resistance of the third transistor 478. In certain cases, the first variable capacitor 480a, the second variable capacitor 480b, and the third transistor 478 may effectively serve as a filter (or attenuator) that attenuates the supply voltage fed to the sources of the first transistor 474 and the second transistor 476 to a suitable bias voltage.

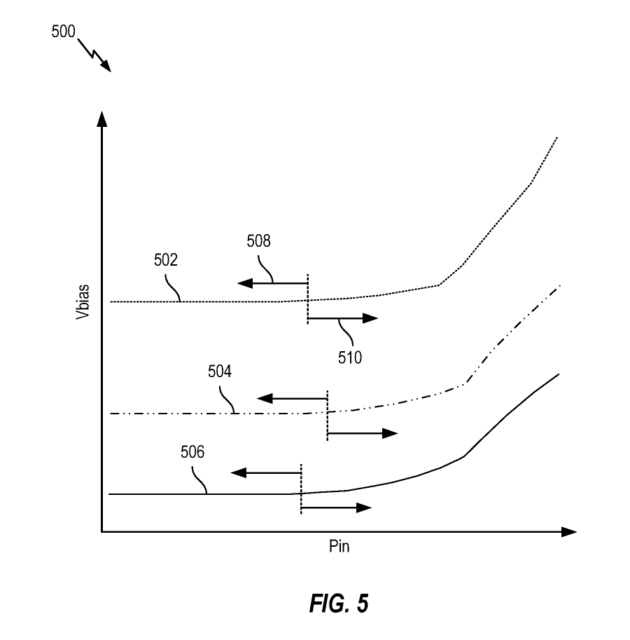

FIG. 5 depicts an example graph 500 of curves of bias voltage (Vbias) of an example dynamic bias circuit over a range of input powers (Pin) of an amplifier. In this example, each of the curves 502, 504, 506 is associated with a different PVT corner of the amplifier (such as the amplifier 312 of FIG. 3). The first curve 502 may represent the bias voltage output by the dynamic bias circuit (e.g., the dynamic bias circuit 304 of FIG. 3) at a range of input powers for a first PVT corner. The second curve 504 may represent the bias voltage output by the dynamic bias circuit at the range of input power for a second PVT corner. The third curve 506 may represent the bias voltage output by the dynamic bias circuit at the range of input powers for a third PVT corner. Each of the curves 502, 504, 506 may include a constant bias region or stage 508 (e.g., a power back-off mode of the amplifier) and an adaptive bias region or stage 510 (e.g., an on mode of the amplifier).

Within the constant bias region 508, the dynamic bias circuit may output the bias voltage at a specific voltage level (or within a threshold range), for example, to enable an amplifier (e.g., an auxiliary amplifier of a Doherty architecture) to operate in a low power state or effectively disabled. Within the adaptive bias region 510, the dynamic bias circuit may output the bias voltage at a voltage level that increases as the input power increases. As an example, the adaptive bias region 510 may allow the amplifier to prime to a suitable gain level (for example, prior to compression of a main amplifier) and then boost the gain during compression. The rate of increase (e.g., the slope) of the bias voltage in the adaptive bias region 510 may be adjusted, for example, using the variable capacitors and/or the third transistor of the second bias generator 332. The rate of increase of the bias voltage may be selected based on calibration, performance monitoring, the current PVT corner, and/or the like. The replica circuit-based feedback of the first bias generator 330 may allow the dynamic bias generator to provide adaptive biasing that accounts for various PVT corners of the amplifier circuitry along with the voltage peak detector of the second bias generator 332. Accordingly, the dynamic bias circuit described herein may enable improved efficiency (e.g., drain efficiency) by providing biasing across various PVT corners associated with amplifier circuitry.

FIG. 6A depicts an example of a multi-stage amplifier architecture 600A employing one or more dynamic bias circuits. In this example, the multi-stage amplifier architecture 600A may include a first amplifier circuit 602a and a second amplifier circuit 602b coupled to the first amplifier circuit 602a. Each of the first amplifier circuit 602a and the second amplifier circuit 602b may be an example of the amplifier circuit 302 of FIG. 3. The first amplifier circuit 602a may feed an amplified signal to differential input ports of the second amplifier circuit 602b. The first amplifier circuit 602a may be or include a driver (predriver) amplifier, which may serve as buffer amplifier between other circuitry (not shown) and the second amplifier circuit 602b. The second amplifier circuit 602b may be or include a main amplifier, such as the PA 230.

The multi-stage amplifier architecture 600A may include a first dynamic bias circuit 604a coupled to the first amplifier circuit 602a. The first dynamic bias circuit may be coupled to the first amplifier circuit 602a, for example, as described herein with respect to FIG. 3. The first dynamic bias circuit 604a may feed a bias voltage to the first amplifier circuit 602a, as described herein with respect to FIG. 3.

In certain cases, the multi-stage amplifier architecture 600A may also include a second dynamic bias circuit 604b coupled to the second amplifier circuit 602b, for example, as described herein with respect to FIG. 3. Each of the first dynamic bias circuit 604a and the second dynamic bias circuit 604b may be an example of the dynamic bias circuit 304 described herein with respect to FIGS. 3 and 4. In certain cases, the multi-stage amplifier architecture 600A may include the first dynamic bias circuit 604a without the second dynamic bias circuit 604b, or vice versa.

FIG. 6B depicts an example of a Doherty amplifier architecture 600B employing one or more dynamic bias circuits. In this example, the Doherty amplifier architecture 600B includes a main amplifier circuit 606a and an auxiliary amplifier circuit 606b. The main amplifier circuit 606a may include a Class A amplifier, Class B amplifier, and/or a Class AB amplifier; and the auxiliary amplifier circuit 606b may include a Class C amplifier, which may boost the overall gain of the Doherty amplifier when the main amplifier circuit 606a begins to compress. The Doherty amplifier architecture 600B may include a first dynamic bias circuit 608a coupled to the auxiliary amplifier circuit 606a, for example, as described herein with respect to FIGS. 3 and 4. In certain aspects, the Doherty amplifier architecture 600B may also include a second dynamic bias circuit 608b coupled to the main amplifier circuit 606a, for example, as described herein with respect to FIGS. 3 and 4. In certain cases, the Doherty amplifier architecture 600B may include the first dynamic bias circuit 608a without the second dynamic bias circuit 608b, or vice versa.

Note that the Doherty amplifier architecture 600B is an example of a Doherty amplifier circuit. Aspects of the present disclosure may be applied to other Doherty architectures, such as an architecture that employs quarter wavelength transmission lines between the inputs and the outputs of amplifiers 606a, 606b. The Doherty amplifier architecture 600B may include other elements not shown for each of illustration (e.g., phase shifters, combining circuitry, and the like).

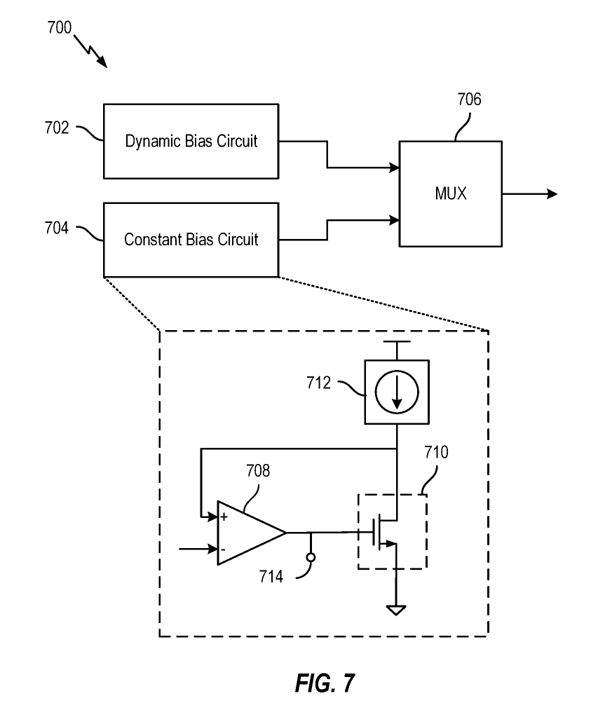

FIG. 7 depicts an example selective bias architecture 700 that includes multiple bias circuits. In this example, the architecture 700 may include a first bias circuit 702, a second bias circuit 704, and a multiplexer 706. The first bias circuit 702 may be or include a dynamic bias circuit (such as the dynamic bias circuit 304 of FIG. 3), and the second bias circuit 704 may be or include a constant bias circuit. The second bias circuit 704 may be configured to output a bias voltage at a specific voltage level, for example, within a threshold voltage range (e.g., ±0.1%, 1%, 5%, or the like). The second bias circuit 704 may include an operational amplifier 708, a g m device 710 (which may be a replica transistor of the input stage transistor of an amplifier circuit), and a current source 712. As an example, the operational amplifier 708 may have an inverting input, a non-inverting input, and an output. A reference voltage may be fed to the inverting input of the operational amplifier, and the non-inverting input may be coupled to the current source 712 and a drain of the g m device 710. The output of the operational amplifier may be coupled to the gate of the g m device 710. The second bias circuit 704 may feed the bias voltage to the multiplexer 706 via an output node 714.

Each of the first bias circuit 702 and the second bias circuit 704 may be selectively coupled to an amplifier circuit (such as the amplifier circuit 302 of FIG. 3) via the multiplexer 706. For example, the multiplexer 706 may be coupled between the outputs of the bias circuits 702, 704 and the differential input stage of the amplifier circuit. Each of the first bias circuit 702 and the second bias circuit 704 may feed a respective bias voltage to the differential input stage of the amplifier circuit. The multiplexer 706 may be used to select whether to apply the bias voltage output by the first bias circuit 702 or the second bias circuit 704. As an example, the processor 306 of FIG. 3 may be coupled to the multiplexer 706 to select the bias voltage output by either the first bias circuit 702 or the second bias circuit 704.

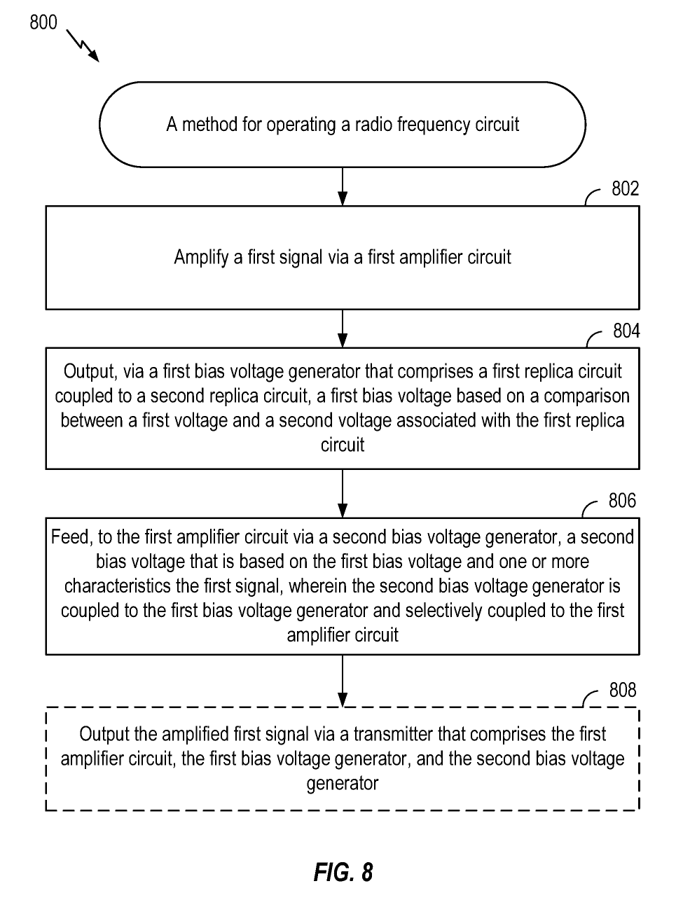

FIG. 8 illustrates example operations 800 for operating an RF circuit. The operations 800 may be performed, for example, by a wireless device (e.g., the first wireless device 102 in the wireless communications system 100). In certain aspects, the operations 800 may be performed, for example, by an RF circuit (e.g., the architecture 300 of the dynamically biased amplifier circuit). The operations 800 may be implemented as software components that are executed and run on one or more processors (e.g., the modem 210 and/or the processor 212 of FIG. 2). Further, the transmission and/or reception of signals by the wireless device in the operations 800 may be enabled, for example, by one or more antennas (e.g., the antenna 220 of FIG. 2). In certain aspects, the transmission and/or reception of signals by the wireless device may be implemented via a bus interface of one or more processors (e.g., the modem 210 and/or the processor 212 of FIG. 2) obtaining and/or outputting signals for reception or transmission.

The operations 800 may optionally begin, at block 802, where the wireless device may amplify a first signal via a first amplifier circuit (e.g., the amplifier circuit 302 of FIG. 3).

At block 804, the wireless device may output, via a first bias voltage generator (e.g., the first bias generator 330 of FIG. 3) that comprises a first replica circuit coupled to a second replica circuit, a first bias voltage based on a comparison between a first voltage and a second voltage associated with the first replica circuit.

At block 806, the wireless device may feed, to the first amplifier circuit via a second bias voltage generator (e.g., the second bias generator 332 of FIG. 3), a second bias voltage that is based on the first bias voltage and one or more characteristics of the first signal. In certain aspects, the second bias voltage generator is coupled to the first bias voltage generator and selectively coupled to the first amplifier circuit. The one or more characteristics may be or include a power level, a current level, and/or a voltage level of the first signal.

At block 808, the wireless device may output the amplified first signal via a transmitter (e.g., the TX path 218 of FIG. 2) that comprises the first amplifier circuit, the first bias voltage generator, and the second bias voltage generator. The wireless device may include an antenna coupled to the transmitter, and the wireless device may transmit the signal via the antenna. As an example, the wireless device may feed the signal to the antenna for transmission. In certain cases, the wireless device may transmit the first signal to another wireless communication device (e.g., any of the second wireless devices 104 depicted in FIG. 1). The first signal may indicate (or carry) any of various information, such as data and/or control information. In some cases, the first signal may indicate (or carry) one or more packets or data blocks.

In certain aspects, the operations 800 include feeding, via an output of an operational amplifier of the first bias voltage generator, the first bias voltage to the second replica circuit; feeding, via the second replica circuit, a third bias voltage to the first replica circuit; feeding, via the first replica circuit, a second signal to a first input of the operational amplifier; and feeding a third signal to a second input of the operational amplifier.

In certain aspects, feeding the third bias voltage comprises feeding the third bias voltage via the second replica circuit that comprises a first transistor, a second transistor, and an output node, wherein a gate of the first transistor is coupled to the output of the operational amplifier, and wherein the output node is coupled between a drain of the first transistor and a gate of the second transistor. In certain aspects, feeding the second signal comprises feeding the second signal via the first replica circuit that comprises a third transistor, wherein a gate of the third transistor is coupled to the output node of the second replica circuit, and wherein a drain of the third transistor is coupled to the first input of the operational amplifier.

In certain aspects, the operations 800 include outputting the second bias voltage via the second bias voltage generator that comprises a voltage peak detector coupled to a variable voltage divider. In certain aspects, outputting the second bias voltage comprises outputting the second bias voltage via the second bias voltage generator that comprises: a first differential input port; a second differential input port; an output node; a first transistor having a gate coupled to the first differential input port and a drain coupled to the output node; a second transistor having a gate coupled to the second differential input port and a drain coupled to the output node; a third transistor having a drain and a gate coupled to the output node; a first variable capacitor coupled to the first differential input port; and a second variable capacitor coupled to the second differential input port.

In certain aspects, the operations 800 include adjusting the second bias voltage based at least in part on a first capacitance of the first variable capacitor, a second capacitance of the second variable capacitor, and a drain-source resistance of the third transistor. In certain aspects, adjusting the second bias voltage comprises adjusting the drain-source resistance of the third transistor.

In certain aspects, feeding the second bias voltage to the first amplifier circuit comprises feeding the second bias voltage to a common mode node of a differential input stage of the first amplifier circuit. In certain aspects, the first amplifier circuit comprises a differential input stage having a third differential input port, a fourth differential input port, and the common mode node; the first differential input port of the second bias voltage generator is coupled to the third differential input port of the first amplifier circuit; the second differential input port of the second bias voltage generator is coupled to the fourth differential input port of the first amplifier circuit; and the output node of the second bias voltage generator is coupled to the common mode node of the first amplifier circuit.

In certain aspects, feeding the second bias voltage comprises feeding the second bias voltage to the common mode node.

In certain aspects, the operations 800 include outputting an output voltage via the second replica circuit that comprises at least one replica transistor associated with the second bias voltage generator.

In certain aspects, the operations 800 include outputting, via the second replica circuit, an output voltage associated with the second bias voltage generator.

In certain aspects, the operations 800 include outputting a second signal via the first replica circuit that comprises at least one replica transistor associated with the first amplifier circuit. In certain aspects, outputting the second signal comprises outputting the second signal via the at least one replica transistor that comprises a channel having at least one dimension that matches a respective dimension of a transistor of the first amplifier circuit within a threshold.

In certain aspects, the operations 800 include feeding the amplified first signal to a second amplifier circuit coupled to the first amplifier circuit; and feeding, to the second amplifier circuit, a third bias voltage via a dynamic bias circuit.

In certain aspects, amplifying the first signal comprises amplifying the first signal via the first amplifier circuit that comprises a Doherty amplifier.

In certain aspects, the operations 800 include feeding, to the first amplifier circuit, a third bias voltage via a third bias voltage generator.

In certain aspects, the operations 800 include outputting the amplified first signal via a transmitter that comprises the first amplifier circuit, the first bias voltage generator, and the second bias voltage generator.

Aspects of the present disclosure may be applied to any of various wireless communication devices that may perform dynamic biasing as described herein.

### Example Aspects

Implementation examples are described in the following numbered clauses:

Aspect 1: A radio frequency (RF) circuit, comprising: a first amplifier circuit configured to amplify a signal; a first bias voltage generator comprising a first replica circuit coupled to a second replica circuit, wherein the first bias voltage generator is configured to output a first bias voltage based on a comparison between a first voltage and a second voltage associated with the first replica circuit; and a second bias voltage generator coupled to the first bias voltage generator and selectively coupled to the first amplifier circuit, wherein the second bias voltage generator is configured to feed, to the first amplifier circuit, a second bias voltage based on the first bias voltage and the signal.

Aspect 2: The RF circuit of Aspect 1, wherein: the first bias voltage generator comprises an operational amplifier having a first input, a second input, and an output; the second replica circuit is coupled between the output of the operational amplifier and the first replica circuit; the first replica circuit is coupled to the first input of the operational amplifier; and the output of the operational amplifier is coupled to the second bias voltage generator.

Aspect 3: The RF circuit of Aspect 2, wherein: the second replica circuit comprises a first transistor, a second transistor, and an output node, wherein a gate of the first transistor is coupled to the output of the operational amplifier, and wherein the output node is coupled between a drain of the first transistor and a gate of the second transistor; and the first replica circuit comprises a third transistor, wherein a gate of the third transistor is coupled to the output node of the second replica circuit, and wherein a drain of the third transistor is coupled to the first input of the operational amplifier.

Aspect 4: The RF circuit according to any of Aspects 1–3, wherein the second bias voltage generator comprises a voltage peak detector coupled to a variable voltage divider.

Aspect 5: The RF circuit of Aspect 4, wherein the second bias voltage generator comprises: a first differential input port; a second differential input port; an output node; a first transistor having a gate coupled to the first differential input port and a drain coupled to the output node; a second transistor having a gate coupled to the second differential input port and a drain coupled to the output node; a third transistor having a drain and a gate coupled to the output node; a first variable capacitor coupled to the first differential input port; and a second variable capacitor coupled to the second differential input port.

Aspect 6: The RF circuit of Aspect 5, further comprising one or more processors coupled to the second bias voltage generator, the one or more processors being configured to adjust the second bias voltage based at least in part on a first capacitance of the first variable capacitor, a second capacitance of the second variable capacitor, and a drain-source resistance of the third transistor.

Aspect 7: The RF circuit of Aspect 6, wherein the third transistor comprises a variable resistance.

Aspect 8: The RF circuit according to any of Aspects 5–7, wherein: the first amplifier circuit comprises a differential input stage having a third differential input port, a fourth differential input port, and a common mode node; the first differential input port of the second bias voltage generator is coupled to the third differential input port of the first amplifier circuit; the second differential input port of the second bias voltage generator is coupled to the fourth differential input port of the first amplifier circuit; and the output node of the second bias voltage generator is coupled to the common mode node of the first amplifier circuit.

Aspect 9: The RF circuit of Aspect 8, wherein the second bias voltage generator is configured to feed the second bias voltage to the common mode node.

Aspect 10: The RF circuit according to any of Aspects 1–9, wherein the second replica circuit comprises at least one replica transistor associated with the second bias voltage generator.

Aspect 11: The RF circuit according to any of Aspects 1–10, wherein the second replica circuit is configured to replicate an output voltage associated with the second bias voltage generator.

Aspect 12: The RF circuit according to any of Aspects 1–11, wherein the first replica circuit comprises at least one replica transistor associated with the first amplifier circuit.

Aspect 13: The RF circuit of Aspect 12, wherein the at least one replica transistor comprises a channel having at least one dimension that matches a respective dimension of a transistor of the first amplifier circuit within a threshold.

Aspect 14: The RF circuit according to any of Aspects 1–13, further comprising: a second amplifier circuit coupled to the first amplifier circuit; and a dynamic bias circuit coupled to the second amplifier circuit.

Aspect 15: The RF circuit according to any of Aspects 1–14, wherein the first amplifier circuit comprises a Doherty amplifier.

Aspect 16: The RF circuit according to any of Aspects 1–15, further comprising a third bias voltage generator selectively coupled to the first amplifier circuit, wherein the third bias voltage generator is configured to feed, to the first amplifier circuit, a third bias voltage.

Aspect 17: The RF circuit according to any of Aspects 1–16, further comprising an antenna and a transmitter comprising the first amplifier circuit, the first bias voltage generator, and the second bias voltage generator, the transmitter coupled to the antenna and configured to transmit the signal via the antenna.

Aspect 18: A method for operating a radio frequency (RF) circuit, comprising: amplifying a first signal via a first amplifier circuit; outputting, via a first bias voltage generator that comprises a first replica circuit coupled to a second replica circuit, a first bias voltage based on a comparison between a first voltage and a second voltage associated with the first replica circuit; and feeding, to the first amplifier circuit via a second bias voltage generator, a second bias voltage that is based on the first bias voltage and one or more characteristics of the first signal, wherein the second bias voltage generator is coupled to the first bias voltage generator and selectively coupled to the first amplifier circuit.

Aspect 19: The method of Aspect 18, further comprising: feeding, via an output of an operational amplifier of the first bias voltage generator, the first bias voltage to the second replica circuit; feeding, via the second replica circuit, a third bias voltage to the first replica circuit; feeding, via the first replica circuit, a second signal to a first input of the operational amplifier; and feeding a third signal to a second input of the operational amplifier.

Aspect 20: The method of Aspect 19, wherein: feeding the third bias voltage comprises feeding the third bias voltage via the second replica circuit that comprises a first transistor, a second transistor, and an output node, wherein a gate of the first transistor is coupled to the output of the operational amplifier, and wherein the output node is coupled between a drain of the first transistor and a gate of the second transistor; and feeding the second signal comprises feeding the second signal via the first replica circuit that comprises a third transistor, wherein a gate of the third transistor is coupled to the output node of the second replica circuit, and wherein a drain of the third transistor is coupled to the first input of the operational amplifier.

Aspect 21: The method according to any of Aspects 18–20, further comprising outputting the second bias voltage via the second bias voltage generator that comprises a voltage peak detector coupled to a variable voltage divider.

Aspect 22: The method of Aspect 21, wherein outputting the second bias voltage comprises outputting the second bias voltage via the second bias voltage generator that comprises: a first differential input port; a second differential input port; an output node; a first transistor having a gate coupled to the first differential input port and a drain coupled to the output node; a second transistor having a gate coupled to the second differential input port and a drain coupled to the output node; a third transistor having a drain and a gate coupled to the output node; a first variable capacitor coupled to the first differential input port; and a second variable capacitor coupled to the second differential input port.

Aspect 23: The method of Aspect 22, further comprising adjusting the second bias voltage based at least in part on a first capacitance of the first variable capacitor, a second capacitance of the second variable capacitor, and a drain-source resistance of the third transistor.

Aspect 24: The method of Aspect 23, wherein adjusting the second bias voltage comprises adjusting the drain-source resistance of the third transistor.

Aspect 25: The method according to any of Aspects 22–24, wherein feeding the second bias voltage to the first amplifier circuit comprises feeding the second bias voltage to a common mode node of a differential input stage of the first amplifier circuit, wherein: the first amplifier circuit comprises a differential input stage having a third differential input port, a fourth differential input port, and the common mode node; the first differential input port of the second bias voltage generator is coupled to the third differential input port of the first amplifier circuit; the second differential input port of the second bias voltage generator is coupled to the fourth differential input port of the first amplifier circuit; and the output node of the second bias voltage generator is coupled to the common mode node of the first amplifier circuit.

Aspect 26: The method of Aspect 25, wherein feeding the second bias voltage comprises feeding the second bias voltage to the common mode node.

Aspect 27: The method according to any of Aspects 18–26, further comprising outputting an output voltage via the second replica circuit that comprises at least one replica transistor associated with the second bias voltage generator.

Aspect 28: The method according to any of Aspects 18–27, further comprising outputting, via the second replica circuit, an output voltage associated with the second bias voltage generator.

Aspect 29: The method according to any of Aspects 18–28, further comprising outputting a second signal via the first replica circuit that comprises at least one replica transistor associated with the first amplifier circuit.

Aspect 30: The method of Aspect 29, wherein outputting the second signal comprises outputting the second signal via the at least one replica transistor that comprises a channel having at least one dimension that matches a respective dimension of a transistor of the first amplifier circuit within a threshold.

Aspect 31: The method according to any of Aspects 18–30, further comprising: feeding the amplified first signal to a second amplifier circuit coupled to the first amplifier circuit; and feeding, to the second amplifier circuit, a third bias voltage via a dynamic bias circuit.

Aspect 32: The method according to any of Aspects 18–31, wherein amplifying the first signal comprises amplifying the first signal via the first amplifier circuit that comprises a Doherty amplifier.

Aspect 33: The method according to any of Aspects 18–32, further comprising feeding, to the first amplifier circuit, a third bias voltage via a third bias voltage generator.

Aspect 34: The method according to any of Aspects 18–33, further comprising outputting the amplified first signal via an antenna coupled to a transmitter that comprises the first amplifier circuit, the first bias voltage generator, and the second bias voltage generator.

Aspect 35: A radio frequency (RF) circuit, comprising: a transceiver comprising: a Doherty amplifier comprising a first amplifier circuit and a second amplifier circuit, wherein the first amplifier circuit is configured to amplify a signal; a first bias voltage generator configured to output a first bias voltage based on a comparison between a first voltage and a second voltage associated with the first amplifier circuit; and a second bias voltage generator coupled to the first bias voltage generator and selectively coupled to the first amplifier circuit, wherein the second bias voltage generator is configured to feed, to the first amplifier circuit, a second bias voltage that is based on the first bias voltage and one or more characteristics the signal.

Aspect 36: The RF circuit of Aspect 35, wherein the first bias voltage generator comprises a first replica circuit, a second replica circuit coupled to the first replica circuit, and an operational amplifier having a first input, a second input, and an output; the second replica circuit is coupled between the output of the operational amplifier and the first replica circuit; the first replica circuit is coupled to the first input of the operational amplifier; and the output of the operational amplifier is coupled to the second bias voltage generator.

Aspect 37: An apparatus, comprising: a memory; and one or more processors configured to perform a method in accordance with any of Aspects 18–34.

Aspect 38: An apparatus, comprising means for performing a method in accordance with any of Aspects 18–34.

Aspect 39: A non-transitory computer-readable medium comprising computer-executable instructions that, when executed by one or more processors of a processing system, cause the processing system to perform a method in accordance with any of Aspects 18–34.

Aspect 40: A computer program product embodied on a computer-readable storage medium comprising code for performing a method in accordance with any of Aspects 18–34.

Aspect 41: A method of manufacturing a radio frequency circuit, comprising making a radio frequency circuit in accordance with any of Aspects 1–17, 35, or 36.

### Additional Considerations

The preceding description is provided to enable any person skilled in the art to practice the various aspects described herein. The examples discussed herein are not limiting of the scope, applicability, or aspects set forth in the claims. Various modifications to these aspects will be readily apparent to those skilled in the art, and the general principles defined herein may be applied to other aspects. For example, changes may be made in the function and arrangement of elements discussed without departing from the scope of the disclosure. Various examples may omit, substitute, or add various procedures or components as appropriate. For instance, the methods described may be performed in an order different from that described, and various actions may be added, omitted, or combined. Also, features described with respect to some examples may be combined in some other examples. For example, an apparatus may be implemented or a method may be practiced using any number of the aspects set forth herein. In addition, the scope of the disclosure is intended to cover such an apparatus or method that is practiced using other structure, functionality, or structure and functionality in addition to, or other than, the various aspects of the disclosure set forth herein. It should be understood that any aspect of the disclosure disclosed herein may be embodied by one or more elements of a claim.

The various illustrative logical blocks, modules and circuits described in connection with the present disclosure may be implemented or performed with a microcontroller, a microprocessor, a general purpose processor, an artificial intelligence (AI) processor, a digital signal processor (DSP), an ASIC, a field programmable gate array (FPGA) or other programmable logic device (PLD), discrete gate or transistor logic, discrete hardware components, or any combination thereof designed to perform the functions described herein. A general purpose processor may be a microprocessor, but in the alternative, the processor may be any commercially available processor, controller, microcontroller, or state machine. A processor may also be implemented as a combination of computing devices, e.g., a combination of a DSP and a microprocessor, a plurality of microprocessors, one or more microprocessors in conjunction with a DSP core, a system on a chip (SoC), a system in package (SiP), or any other such configuration.

As used herein, a phrase referring to “at least one of” a list of items refers to any combination of those items, including single members. As an example, “at least one of: a, b, or c” is intended to cover a, b, c, a-b, a-c, b-c, and a-b-c, as well as any combination with multiples of the same element (e.g., a-a, a-a-a, a-a-b, a-a-c, a-b-b, a-c-c, b-b, b-b-b, b-b-c, c-c, and c-c-c or any other ordering of a, b, and c).

As used herein, the term “determining” encompasses a wide variety of actions. For example, “determining” may include calculating, computing, processing, deriving, investigating, looking up (e.g., looking up in a table, a database or another data structure), ascertaining and or like. Also, “determining” may include receiving (e.g., receiving information), accessing (e.g., accessing data in a memory) or the like. Also, “determining” may include resolving, selecting, choosing, establishing or the like.

As used herein, “coupled to” and “coupled with” generally encompass direct coupling and indirect coupling (e.g., including intermediary coupled aspects) unless stated otherwise. For example, stating that a processor is coupled to a memory allows for a direct coupling or a coupling via an intermediary aspect, such as a bus.

The methods disclosed herein comprise one or more actions for achieving the methods. The method actions may be interchanged with one another without departing from the scope of the claims. In other words, unless a specific order of actions is specified, the order and/or use of specific actions may be modified without departing from the scope of the claims. Further, the various operations of methods described above may be performed by any suitable means capable of performing the corresponding functions. The means may include various hardware and/or software component(s) and/or module(s), including, but not limited to a circuit, an application specific integrated circuit (ASIC), or processor.

The following claims are not intended to be limited to the aspects shown herein, but are to be accorded the full scope consistent with the language of the claims. Reference to an element in the singular is not intended to mean only one unless specifically so stated, but rather “one or more.” The subsequent use of a definite article (e.g., “the” or “said”) with an element (e.g., “the processor”) is not intended to invoke a singular meaning (e.g., “only one”) on the element unless otherwise specifically stated. For example, reference to an element (e.g., “a processor,” “a controller,” “a memory,” “a transceiver,” “an antenna,” “the processor,” “the controller,” “the memory,” “the transceiver,” “the antenna,” etc.), unless otherwise specifically stated, should be understood to refer to one or more elements (e.g., “one or more processors,” “one or more controllers,” “one or more memories,” “one or more transceivers,” etc.). The terms “set” and “group” are intended to include one or more elements, and may be used interchangeably with “one or more.” Where reference is made to one or more elements performing functions (e.g., steps of a method), one element may perform all functions, or more than one element may collectively perform the functions. When more than one element collectively performs the functions, each function need not be performed by each of those elements (e.g., different functions may be performed by different elements) and/or each function need not be performed in whole by only one element (e.g., different elements may perform different sub-functions of a function). Similarly, where reference is made to one or more elements configured to cause another element (e.g., an apparatus) to perform functions, one element may be configured to cause the other element to perform all functions, or more than one element may collectively be configured to cause the other element to perform the functions. Unless specifically stated otherwise, the term “some” refers to one or more. All structural and functional equivalents to the elements of the various aspects described throughout this disclosure that are known or later come to be known to those of ordinary skill in the art are intended to be encompassed by the claims. Moreover, nothing disclosed herein is intended to be dedicated to the public regardless of whether such disclosure is explicitly recited in the claims.

1. A radio frequency (RF) circuit, comprising:
a first amplifier circuit configured to amplify a signal;
a first bias voltage generator comprising a first replica circuit coupled to a second replica circuit, wherein the first bias voltage generator is configured to output a first bias voltage based on a comparison between a first voltage and a second voltage associated with the first replica circuit; and
a second bias voltage generator coupled to the first bias voltage generator and selectively coupled to the first amplifier circuit, wherein the second bias voltage generator is configured to feed, to the first amplifier circuit, a second bias voltage that is based on the first bias voltage and one or more characteristics of the signal.

2. The RF circuit of claim 1, wherein:
the first bias voltage generator comprises an operational amplifier having a first input, a second input, and an output;
the second replica circuit is coupled between the output of the operational amplifier and the first replica circuit;
the first replica circuit is coupled to the first input of the operational amplifier; and
the output of the operational amplifier is coupled to the second bias voltage generator.

3. The RF circuit of claim 2, wherein:
the second replica circuit comprises a first transistor, a second transistor, and an output node, wherein a gate of the first transistor is coupled to the output of the operational amplifier, and wherein the output node is coupled between a drain of the first transistor and a gate of the second transistor; and
the first replica circuit comprises a third transistor, wherein a gate of the third transistor is coupled to the output node of the second replica circuit, and wherein a drain of the third transistor is coupled to the first input of the operational amplifier.

4. The RF circuit of claim 1, wherein the second bias voltage generator comprises a voltage peak detector coupled to a variable voltage divider.

5. The RF circuit of claim 4, wherein the second bias voltage generator comprises:
a first differential input port;
a second differential input port;
an output node;
a first transistor having a gate coupled to the first differential input port and a drain coupled to the output node;
a second transistor having a gate coupled to the second differential input port and a drain coupled to the output node;
a third transistor having a drain and a gate coupled to the output node;
a first variable capacitor coupled to the first differential input port; and
a second variable capacitor coupled to the second differential input port.

6. The RF circuit of claim 5, further comprising one or more processors coupled to the second bias voltage generator, the one or more processors being configured to adjust the second bias voltage based at least in part on a first capacitance of the first variable capacitor, a second capacitance of the second variable capacitor, and a drain-source resistance of the third transistor.

7. The RF circuit of claim 6, wherein the third transistor comprises a variable resistance.

8. The RF circuit of claim 5, wherein:
the first amplifier circuit comprises a differential input stage having a third differential input port, a fourth differential input port, and a common mode node;
the first differential input port of the second bias voltage generator is coupled to the third differential input port of the first amplifier circuit;
the second differential input port of the second bias voltage generator is coupled to the fourth differential input port of the first amplifier circuit; and
the output node of the second bias voltage generator is coupled to the common mode node of the first amplifier circuit.

9. The RF circuit of claim 8, wherein the second bias voltage generator is configured to feed the second bias voltage to the common mode node.

10. The RF circuit of claim 1, wherein the second replica circuit comprises at least one replica transistor associated with the second bias voltage generator.

11. The RF circuit of claim 1, wherein the second replica circuit is configured to replicate an output voltage associated with the second bias voltage generator.

12. The RF circuit of claim 1, wherein the first replica circuit comprises at least one replica transistor associated with the first amplifier circuit.

13. The RF circuit of claim 12, wherein the at least one replica transistor comprises a channel having at least one dimension that matches a respective dimension of a transistor of the first amplifier circuit within a threshold.

14. The RF circuit of claim 1, further comprising:
a second amplifier circuit coupled to the first amplifier circuit; and
a dynamic bias circuit coupled to the second amplifier circuit.

15. The RF circuit of claim 1, wherein the first amplifier circuit comprises a Doherty amplifier.

16. The RF circuit of claim 1, further comprising a third bias voltage generator selectively coupled to the first amplifier circuit, wherein the third bias voltage generator is configured to feed, to the first amplifier circuit, a third bias voltage.

17. The RF circuit of claim 1, further comprising an antenna and a transmitter comprising the first amplifier circuit, the first bias voltage generator, and the second bias voltage generator, the transmitter coupled to the antenna and configured to transmit the signal via the antenna.

18. A method for operating a radio frequency (RF) circuit, comprising:
amplifying a first signal via a first amplifier circuit;
outputting, via a first bias voltage generator that comprises a first replica circuit coupled to a second replica circuit, a first bias voltage based on a comparison between a first voltage and a second voltage associated with the first replica circuit; and
feeding, to the first amplifier circuit via a second bias voltage generator, a second bias voltage that is based on the first bias voltage and one or more characteristics of the first signal, wherein the second bias voltage generator is coupled to the first bias voltage generator and selectively coupled to the first amplifier circuit.

19. A radio frequency (RF) circuit, comprising:
a transceiver comprising:
a Doherty amplifier comprising a first amplifier circuit and a second amplifier circuit, wherein the first amplifier circuit is configured to amplify a signal;
a first bias voltage generator configured to output a first bias voltage based on a comparison between a first voltage and a second voltage associated with the first amplifier circuit; and
a second bias voltage generator coupled to the first bias voltage generator and selectively coupled to the first amplifier circuit, wherein the second bias voltage generator is configured to feed, to the first amplifier circuit, a second bias voltage that is based on the first bias voltage and one or more characteristics of the signal.

20. The RF circuit of claim 19, wherein
the first bias voltage generator comprises a first replica circuit, a second replica circuit coupled to the first replica circuit, and an operational amplifier having a first input, a second input, and an output;
the second replica circuit is coupled between the output of the operational amplifier and the first replica circuit;
the first replica circuit is coupled to the first input of the operational amplifier; and
the output of the operational amplifier is coupled to the second bias voltage generator.
